(19) United States
(12) Patent Application Publication
(10) Pub. No.: US 2025/0374651 A1
(43) Pub. Date: Dec. 4, 2025

(54) SEMICONDUCTOR DEVICE INCLUDING A COMPLEMENTARY FIELD-EFFECT TRANSISTOR (CFET) HAVING VERTICALLY STACKED CHANNEL LAYERS

(71) Applicant: SAMSUNG ELECTRONICS CO., LTD., SUWON-SI (KR)

(72) Inventors: Suk YANG, Suwon-si (KR); Jinbum KIM, Suwon-si (KR); Bongjin KUH, Suwon-si (KR); Soomin SON, Suwon-si (KR); Inhae ZOH, Suwon-si (KR)

(21) Appl. No.: 18/956,824

(22) Filed: Nov. 22, 2024

(30) Foreign Application Priority Data
Jun. 3, 2024 (KR) 10-2024-0072648

(51) Int. Cl. H01L 21/8238; H01L 21/822; H01L 27/092; H01L 29/06; H01L 29/08; H01L 29/423; H01L 29/66; H01L 29/775; H01L 29/786

(52) U.S. Cl. CPC H10D 84/017; H10D 30/014; H10D 30/43; H10D 30/6735; H10D 30/6757; H10D 62/121; H10D 62/151; H10D 64/017; H10D 84/0167; H10D 84/038; H10D 84/856; H10D 88/01

(57) ABSTRACT

A semiconductor device includes: a lower stack including a plurality of lower gate lines and a plurality of lower nanosheets that are alternately stacked on a substrate; an upper stack including a plurality of upper gate lines and a plurality of upper nanosheets that are alternately stacked on the lower stack; a lower source/drain region disposed on a side surface of the lower stack; and an upper source/drain region disposed on the lower source/drain region and adjacent to a side surface of the upper stack, wherein the upper source/drain region includes a side impurity layer and an upper center impurity layer, wherein the side impurity layer extends in a vertical direction along the side surface of the upper stack, and the upper center impurity layer is disposed on an inner side of the side impurity layer, and a first surface of the upper center impurity layer has a curved shape.

### CROSS-REFERENCE TO RELATED APPLICATION

This application claims priority under 35 U.S.C. § 119 to Korean Patent Application No. 10-2024-0072648, filed on Jun. 3, 2024, in the Korean Intellectual Property Office, the disclosure of which is incorporated by reference herein in its entirety.

### TECHNICAL FIELD

The present inventive concept relates to a semiconductor device, and more particularly, to a semiconductor device including a complementary field-effect transistor (CFET) having vertically stacked channel layers.

### DISCUSSION OF THE RELATED ART

As the size of integrated circuit devices decreases, the integration density of FETs on a substrate increases. Accordingly, technology for vertically stacking gate-all-around (GAA) transistors in a same layout region is currently under development. By stacking transistors vertically, cell interference may be minimized and many transistors may be integrated in a narrow space.

When an upper source/drain is formed only by epitaxial growth, the upper source/drain might not be completely formed. In this case, the reliability of integrated circuit devices may deteriorate.

### SUMMARY

According to embodiments of the present inventive concept, a semiconductor device includes: a lower stack including a plurality of lower gate lines and a plurality of lower nanosheets that are alternately stacked layer-by-layer on a substrate; an upper stack including a plurality of upper gate lines and a plurality of upper nanosheets that are alternately stacked layer-by-layer on the lower stack; a lower source/drain region disposed on a side surface of the lower stack; and an upper source/drain region disposed on the lower source/drain region and adjacent to a side surface of the upper stack, wherein the upper source/drain region includes a side impurity layer and an upper center impurity layer, wherein the side impurity layer extends in a vertical direction along the side surface of the upper stack, and the upper center impurity layer is disposed on an inner side of the side impurity layer, and a first surface of the upper center impurity layer has a curved shape.

According to embodiments of the present inventive concept, a semiconductor device includes: a lower stack including a plurality of lower gate lines and a plurality of lower nanosheets that are alternately stacked layer-by-layer on a substrate, wherein the plurality of lower gate lines extend in a first horizontal direction; an upper stack including a plurality of upper gate lines and a plurality of upper nanosheets that are alternately stacked layer-by-layer on the lower stack, wherein the plurality of upper gate lines extending in the first horizontal direction; a lower source/drain region adjacent to a side surface of the lower stack; and an upper source/drain region disposed on the lower source/drain region and adjacent to a side surface of the upper stack, wherein the upper source/drain region includes a side impurity layer and an upper center impurity layer, wherein the side impurity layer extends in a vertical direction along the side surface of the upper stack, and the upper center impurity layer is disposed on first side of the side impurity layer, and a sidewall of the upper center impurity layer in the first horizontal direction has a curved shape.

According to embodiments of the present inventive concept, a semiconductor device includes: a substrate including a fin-type active region that extends in a first horizontal direction; a lower stack including a plurality of lower gate lines and a plurality of lower nanosheets that are alternately stacked layer-by-layer on the fin-type active region of the substrate, wherein the plurality of lower gate lines extend in a second horizontal direction that crosses the first horizontal direction; an insulating layer disposed on the lower stack; an upper stack including a plurality of upper gate lines and a plurality of upper nanosheets that are alternately stacked layer-by-layer on the insulating layer, wherein the plurality of upper gate lines extend in the second horizontal direction; a placeholder arranged in the substrate and below the lower stack; a lower source/drain region disposed on the placeholder and adjacent to a side surface of the lower stack; and an upper source/drain region adjacent to a side surface of the upper stack, wherein the upper source/drain region includes a side impurity layer and an upper center impurity layer, wherein the side impurity layer extends in a vertical direction along the side surface of the upper stack, and the upper center impurity layer is disposed on an inner side of the side impurity layer, and a top surface of the upper center impurity layer has a curved shape.

### BRIEF DESCRIPTION OF THE DRAWINGS

The above and other aspects of the present inventive concept will become more apparent by describing in detail embodiments thereof, with reference to the accompanying drawings, in which:

FIG. 1 is a plane layout diagram of a semiconductor device according to embodiments of the present inventive concept;

FIGS. 2A and 2B are cross-sectional views respectively taken along line I-I′ and line II-II′ in FIG. 1, according to an embodiment of the present inventive concept;

FIG. 3 is a cross-sectional view taken along line II-II′ in FIG. 1, according to embodiments of the present inventive concept; and

FIGS. 4, 5A, 5B, 6, 7, 8, 9A, 9B, 10A, 10B, 11A, 11B, 12A, 12B, 13A, 13B, 14, 15A, 15B, 16A, 16B, 17A, 17B, 18A, 18B, 19A, 19B, 20, and 21 are plan views and cross-sectional views illustrating a method of manufacturing a semiconductor device, according to an embodiment of the present inventive concept.

### DETAILED DESCRIPTION OF THE EMBODIMENTS

Hereinafter, embodiments of the present inventive concept are described in detail with reference to the accompanying drawings. In the drawing, like reference characters denote like elements throughout the specification and drawings, and redundant descriptions thereof will be omitted.

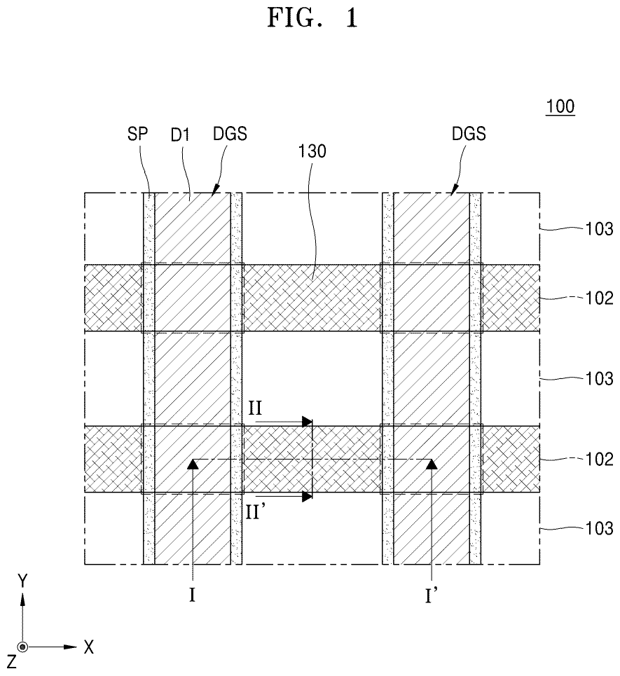

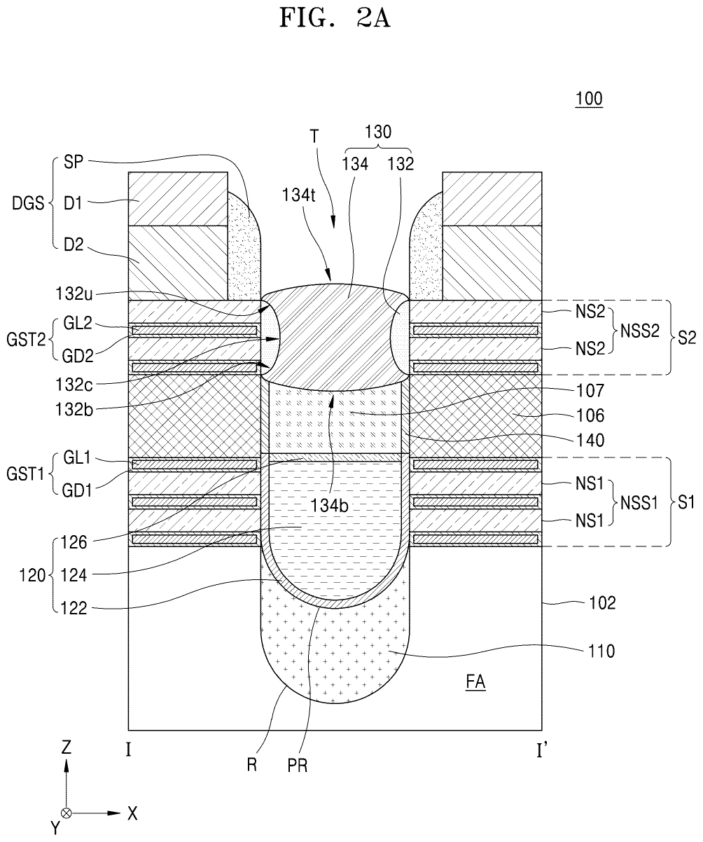

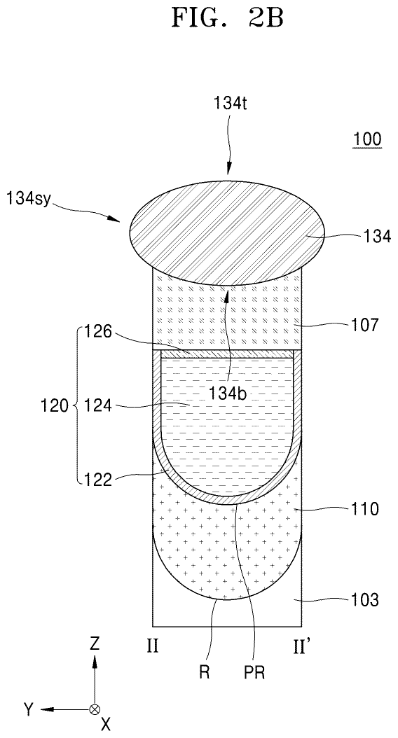

FIG. 1 is a plane layout diagram of a semiconductor device 100 according to embodiments the present inventive concept. FIGS. 2A and 2B are cross-sectional views respectively taken along line I-I′ and line II-II′ in FIG. 1, according to an embodiment of the present inventive concept.

Referring to FIGS. 1 to 2B, according to an embodiment of the present inventive concept, the semiconductor device 100 may include a substrate 102, a lower stack S1, an insulating layer 106, an upper stack S2, a placeholder 110, a lower source/drain region 120, and an upper source/drain region 130.

In an embodiment of the present inventive concept, the semiconductor device 100 may refer to a semiconductor device in a stage, in which a source/drain region is formed by epitaxial growth, in a method of manufacturing a logic device.

The substrate 102 may include a semiconductor, such as Si or Ge, or a compound semiconductor, such as SiGe, SiC, GaAs, InAs, InGaAs, or InP. A plurality of fin-type active regions FA may protrude from the top surface of the substrate 102 in a vertical direction Z.

The fin-type active regions FA may extend lengthwise on the top surface of the substrate 102 in a first horizontal direction X and may be spaced apart from each other in a second horizontal direction Y that is substantially perpendicular to the first horizontal direction X.

An isolation film 103 may be disposed on the substrate 102 and may cover opposite sidewalls of each of the fin-type active regions FA. The isolation film 103 may include, for example, an oxide film, a nitride film, or a combination thereof.

The lower stack S1 may include a plurality of lower gate lines GL1 and a plurality of lower nanosheets NS1 alternately stacked with the lower gate lines GL1.

In regions in which the fin-type active regions FA intersect with the lower gate lines GL1, a plurality of lower nanosheet stacks NSS1 may be disposed on the top surfaces of the fin-type active regions FA.

The lower nanosheet stacks NSS1 each may include a plurality of lower nanosheets NS1, which are spaced apart from each other in the vertical direction Z. Here, as a conductive structure through which current flows, a nanosheet may have a flat shape. In addition, the nanosheet may include, for example, a nanowire having a string shape.

The lower nanosheets NS1 may have different vertical distances (or different Z-direction distances) from the top surface of a fin-type active region FA. Here, the lower nanosheets NS1 may include a conductive structure through which current flows. Although it is illustrated in FIG. 2A that one lower nanosheet stack NSS1 includes two lower nanosheets NS1, the number of lower nanosheets NS1 included in one lower nanosheet stack NSS1 is not limited thereto.

The lower gate lines GL1 may be disposed on the fin-type active region FA and the isolation film 103. The lower gate lines GL1 may extend across the fin-type active region FA in the second horizontal direction Y that crosses the first horizontal direction X. The lower gate lines GL1 may be apart from each other in the first horizontal direction X.

The lower gate lines GL1 may include, for example, metal, metal nitride, metal carbide, or a combination thereof. For example, the metal may include Ti, W, Ru, Nb, Mo, Hf, Ni, Co, Pt, Yb, Tb, Dy, Er, or Pd. For example, the metal nitride may include TiN or TaN. For example, the metal carbide may include TiAlC.

A lower gate dielectric film GD1 may be between the lower nanosheet stack NSS1 and a lower gate line GL1. Opposite sidewalls of the lower gate line GL1 in the first horizontal direction X may be separated from the lower source/drain region 120 by the lower gate dielectric film GD1.

The top and bottom surfaces of the lower gate line GL1 may be separated from a lower nanosheet NS1, the top surface of the fin-type active region FA, and the bottom surface of the insulating layer 106 by the lower gate dielectric film GD1.

The lower gate line GL1 and the lower gate dielectric film GD1 may form a lower gate structure GST1. The lower gate structure GST1 may extend in the second horizontal direction Y on the fin-type active region FA and the isolation film 103.

The insulating layer 106 may be disposed on the lower stack S1. The insulating layer 106 may be between the lower stack S1 and the upper stack S2 and may separate and insulate the lower source/drain region 120 from the upper source/drain region 130. For example, the insulating layer 106 may include, but is not limited to, SiNx, SiO₂, SiON, SiOCN, or a combination thereof.

The upper stack S2 may include a plurality of upper gate lines GL2 and a plurality of upper nanosheets NS2 that are alternately stacked with the upper gate lines GL2.

The upper stack S2 may be spaced apart from the lower stack S1 in the vertical direction Z. The upper stack S2 may be adjacent to the lower stack S1 with the insulating layer 106 between the upper stack S2 and the lower stack S1. An upper gate line GL2 may correspond to a lower gate line GL1. For example, the upper gate line GL2 may overlap the lower gate line GL1. An upper nanosheet NS2 may correspond to a lower nanosheet NS1. For example, the upper nanosheet NS2 may overlap the lower nanosheet NS1.

A plurality of upper nanosheet stacks NSS2 may be disposed in regions in which the plurality of fin-type active regions FA intersect with the plurality of upper gate lines GL2. The upper nanosheet stacks NSS2 each may include a plurality of upper nanosheets NS2, which are spaced apart from each other in the vertical direction Z.

The upper nanosheets NS2 may have different vertical distances (or different Z-direction distances) from the top surface of a fin-type active region FA. Although it is illustrated in FIG. 2A that one upper nanosheet stack NSS2 includes two upper nanosheets NS2, the number of upper nanosheets NS2 included in one upper nanosheet stack NSS2 is not limited thereto.

The upper gate lines GL2 may be disposed above the fin-type active region FA and the isolation film 103. The upper gate lines GL2 may extend across the fin-type active region FA in the second horizontal direction Y that crosses the first horizontal direction X. The upper gate lines GL2 may be spaced apart from each other in the first horizontal direction X.

An upper gate dielectric film GD2 may be between the upper nanosheet stack NSS2 and an upper gate line GL2. Opposite sidewalls of the upper gate line GL2 in the first horizontal direction X may be separated from the upper source/drain region 130 by the upper gate dielectric film GD2. The top and bottom surfaces of the upper gate line GL2 may be separated from an upper nanosheet NS2 and the top surface of the insulating layer 106 by upper gate dielectric film GD2.

The upper gate line GL2 and the upper gate dielectric film GD2 may form an upper gate structure GST2. The upper gate structure GST2 may extend in the second horizontal direction Y on the fin-type active region FA and the isolation film 103.

A plurality of trenches T may be formed in the fin-type active region FA. Here, a trench T may include a recess R in an upper portion of the fin-type active region FA. Accordingly, the trench T may be defined by the top surface of the upper nanosheet stack NSS2 and the bottom surface of the recess R that is formed in the upper portion of the fin-type active region FA.

The placeholder 110, the lower source/drain region 120, the upper source/drain region 130, and a liner 140 may be arranged in the trench T.

The placeholder 110 may be disposed on the substrate 102 and arranged in the trench T. The placeholder 110 may fill the recess R of the fin-type active region FA and may be disposed below the lower stack S1.

The placeholder 110 may include a placeholder recess PR in an upper portion thereof. The lower source/drain region 120 may be in contact with the placeholder recess PR. The placeholder 110 may include an epitaxial layer, i.e., an epitaxially grown semiconductor layer. In an embodiment of the present inventive concept, the placeholder 110 may include an epitaxially grown SiGe layer.

The lower source/drain region 120 may be disposed on the placeholder 110 and may be adjacent to a side surface of the lower stack S1. The lower source/drain region 120 may be in contact with the side surface of the lower stack S1. The lower source/drain region 120 may include an epitaxial layer, i.e., an epitaxially grown semiconductor layer. The lower source/drain region 120 may include an epitaxially grown Si or SiGe layer.

In an embodiment of the present inventive concept, the lower source/drain region 120 may form an N-channel metal-oxide semiconductor (NMOS) transistor. In this case, the lower source/drain region 120 may include an Si layer doped with an n-type dopant or an SiC layer doped with an n-type dopant, wherein the n-type dopant may be selected from among phosphorous (P), arsenic (As), and antimony (Pb).

The lower source/drain region 120 may include an outer impurity layer 122, a lower center impurity layer 124, and a capping layer 126, which are sequentially stacked away from the fin-type active region FA in the vertical direction Z. For example, the outer impurity layer 122, the lower center impurity layer 124, and the capping layer 126 may be sequentially stacked on the placeholder 110 in the vertical direction Z.

The outer impurity layer 122 may have a structure at least partially surrounding the lower center impurity layer 124. The outer impurity layer 122 may be in contact with the top surface of the placeholder 110 and a side surface of the lower stack S1, which includes the lower gate line GL1 and the lower nanosheet NS1. In other words, the outer impurity layer 122 may be disposed on the placeholder recess PR and may extend in the vertical direction Z along the side surface of the lower stack S1.

In embodiments of the present inventive concept, the outer impurity layer 122 may conformally grow and have an overall substantially uniform thickness. Accordingly, the thickness of the outer impurity layer 122 on the side surface of the lower center impurity layer 124 may be similar to the thickness of the outer impurity layer 122 on the bottom surface of the lower center impurity layer 124. In an embodiment of the present inventive concept, the outer impurity layer 122 may include SiGe doped with P, As, or Pb.

The lower center impurity layer 124 may be disposed on the inner side of the outer impurity layer 122. In an embodiment of the present inventive concept, the lower center impurity layer 124 may include SiGe doped with P, As, or Pb.

A Ge concentration that is in the lower center impurity layer 124 may be greater than a Ge concentration that is in the outer impurity layer 122. A Ge concentration that is in the placeholder 110 may be less than the Ge concentration that is in the lower center impurity layer 124 and greater than the Ge concentration that is in the outer impurity layer 122. Accordingly, in a subsequent process, only the placeholder 110 may be removed separately from the outer impurity layer 122.

The capping layer 126 may cover the top surface of the lower center impurity layer 124. The capping layer 126 may include, for example, undoped Si or SiGe with a low concentration of Ge.

The upper source/drain region 130 may be adjacent to a side surface of the upper stack S2. The upper source/drain region 130 may include an epitaxial layer, i.e., an epitaxially grown semiconductor layer. The upper source/drain region 130 may include an epitaxially grown SiGe layer.

In an embodiment of the present inventive concept, the upper source/drain region 130 may form a P-channel MOS (PMOS) transistor. In this case, the upper source/drain region 130 may include an SiGe layer doped with a p-type dopant, which may be selected from boron (B) and gallium (Ga).

The upper source/drain region 130 may include a side impurity layer 132 and an upper center impurity layer 134.

The side impurity layer 132 may be at a side of the upper center impurity layer 134. For example, the side impurity layer 132 may extend in the vertical direction Z along the side surface of the upper center impurity layer 134. The side impurity layer 132 may be in contact with a side surface of the upper gate structure GST2 and the side surface of the upper stack S2. In other words, the side impurity layer 132 may extend in the vertical direction Z along the side surface of the upper stack S2.

The side impurity layer 132 may include, for example, Si, SiGe, or SiC. Desirably, the side impurity layer 132 may include SiGe but is not limited thereto. When each of the side impurity layer 132 and the upper center impurity layer 134 includes SiGe, a Ge concentration that is in the side impurity layer 132 may be less than a Ge concentration that is in the upper center impurity layer 134. In an embodiment of the present inventive concept, the Ge concentration that is in the side impurity layer 132 may be greater than 0 wt % and less than or equal to about 5 wt %, about 10 wt %, about 20 wt %, or about 30 wt %.

In an embodiment of the present inventive concept, the side impurity layer 132 may include, for example, Si, SiGe, or SiC, which is doped with B. In an embodiment of the present inventive concept, a B concentration in the side impurity layer 132 may be about 10¹⁵ atoms/cm³ to about 10²⁰ atoms/cm³. Desirably, the B concentration in the side impurity layer 132 may be about 10¹⁶ atoms/cm³ to about 10¹⁹ atoms/cm³, but the present inventive concept is not limited thereto.

The side impurity layer 132 may include a central region 132c, an upper region 132u, and a lower region 132b. The central region 132c of the side impurity layer 132 may correspond to a central portion of the side impurity layer 132 and may include a portion having the greatest thickness in the side impurity layer 132 in the first horizontal direction X. For example, the central region 132c may have a thickness that is greater than each of a thickness of the upper region 132u and a thickness of the lower region 132b.

The upper region 132u of the side impurity layer 132 may correspond to a portion of the side impurity layer 132, which extends upwards (in the vertical direction Z) from the central region 132c of the side impurity layer 132. The lower region 132b of the side impurity layer 132 may correspond to a portion of the side impurity layer 132, which extends downwards (in the vertical direction Z) from the central region 132c of the side impurity layer 132.

The thickness of the upper region 132u of the side impurity layer 132 in the first horizontal direction X may decrease along an upward direction (in the vertical direction Z). The thickness of the lower region 132b of the side impurity layer 132 in the first horizontal direction X may decrease along the downward direction (in the vertical direction Z).

The side impurity layer 132 may be close to an upper nanosheet NS2, which functions as a channel, and may be doped with a lower concentration of dopant than the upper center impurity layer 134 and may thus prevent a short channel effect.

The upper center impurity layer 134 may be disposed on the inner side of the side impurity layer 132. In an embodiment of the present inventive concept, the upper center impurity layer 134 may include SiC that is doped with a high concentration of B or SiGe that is doped with a high concentration of B.

A Ge concentration that is in the upper center impurity layer 134 may be greater than a Ge concentration that is in the side impurity layer 132. In an embodiment of the present inventive concept, the Ge concentration that is in the upper center impurity layer 134 may be greater than about 30 wt % and less than or equal to about 60 wt %, about 40 wt % to about 55 wt %, or about 47 wt % to about 53 wt %.

A B concentration that is in the upper center impurity layer 134 may be greater than a B concentration that is in the side impurity layer 132. In an embodiment of the present inventive concept, the B concentration that is in the upper center impurity layer 134 may be about 10²⁰ atoms/cm³ to about 10²² atoms/cm³. Desirably, the B concentration that is in the upper center impurity layer 134 may be about 5×10²⁰ atoms/cm³ to about 5×10²¹ atoms/cm³.

A top surface 134t of the upper center impurity layer 134 may have a curved shape. The radius of curvature of the top surface 134t of the upper center impurity layer 134 may vary. The highest vertical level of the top surface 134t of the upper center impurity layer 134 may be higher than the top surface of the topmost one of the upper nanosheets NS2.

The bottom surface 134b of the upper center impurity layer 134 may have a curved shape. The radius of curvature of the bottom surface 134b of the upper center impurity layer 134 may vary. The lowest vertical level of the bottom surface 134b of the upper center impurity layer 134 may be lower than the bottom surface of the bottommost one of the upper nanosheets NS2.

A sidewall 134sy of the upper center impurity layer 134 in the second horizontal direction Y may have a curved shape. The radius of curvature of the sidewall 134sy of the upper center impurity layer 134 in the second horizontal direction Y may vary.

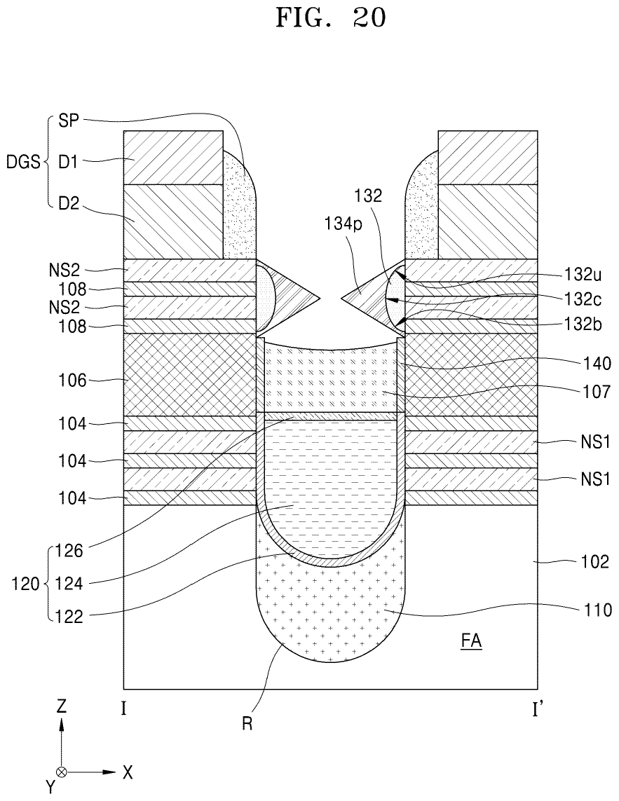

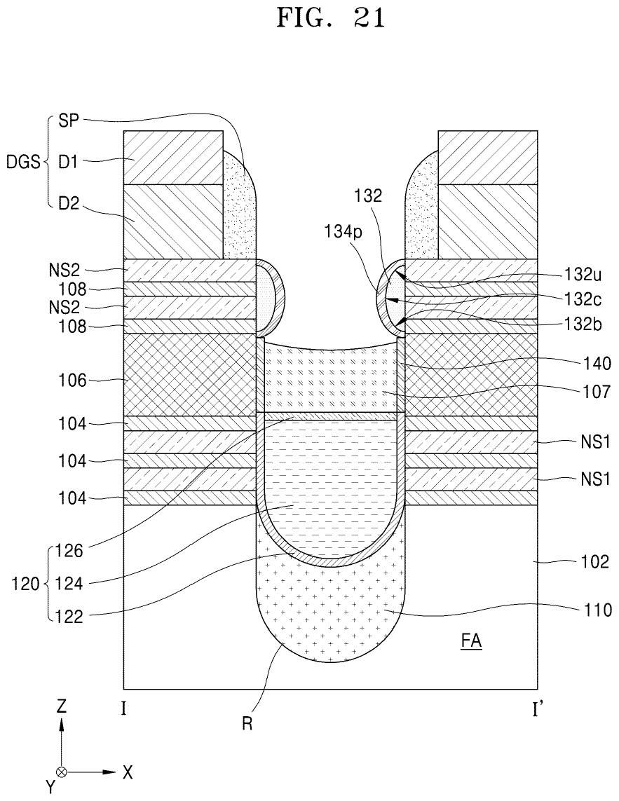

The top surface 134t and the bottom surface 134b of the upper center impurity layer 134 and the sidewall 134sy of the upper center impurity layer 134 in the second horizontal direction Y each may have a curved shape because of a method of forming the upper center impurity layer 134. This is described in detail with reference to FIGS. 20 and 21 below.

The upper center impurity layer 134 may cover the central region 132c of the side impurity layer 132. In an embodiment of the present inventive concept, the upper center impurity layer 134 may cover the upper region 132u and the lower region 132b of the side impurity layer 132. In an embodiment of the present inventive concept, the upper center impurity layer 134 may cover the topmost surface of the upper region 132u of the side impurity layer 132 and the bottommost surface of the lower region 132b of the side impurity layer 132. In an embodiment of the present inventive concept, the upper center impurity layer 134 may cover a side surface of the upper stack S2. For example, the upper center impurity layer 134 may cover the whole side surface of the upper stack S2.

The liner 140 may be between the lower source/drain region 120 and the upper source/drain region 130. For example, the liner 140 may be adjacent to the top surface of the lower source/drain region 120 and a side surface of the insulating layer 106.

The liner 140 may extend in the vertical direction Z along the sidewall of the insulating layer 106 from the topmost surface of the outer impurity layer 122 to the bottom surface 134b of the upper center impurity layer 134. The vertical level of the top surface of the liner 140 may be lower than the vertical level of the top surface of the insulating layer 106. Accordingly, the upper source/drain region 130 may be formed on the side surface of the upper stack S2. The liner 140 may include, for example, SiN, SiO, SiON, or a combination thereof.

In an embodiment of the present inventive concept, an insulating film 107 may be between sidewalls of the insulating layer 106 in the first horizontal direction X. The insulating film 107 may fill the space between the lower source/drain region 120 and the upper source/drain region 130 in the vertical direction Z. In embodiments of the present inventive concept, the insulating film 107 may include SiNx, SiO₂, SiON, SiOCN, or a combination thereof.

A plurality of dummy gate structures DGS may be disposed on the upper stack S2. Each of the dummy gate structures DGS may include a dummy gate layer D1 and a dummy capping layer D2, which are sequentially stacked, and an insulating spacer SP, which covers sidewalls of the dummy gate layer D1 and the dummy capping layer D2.

In embodiments of the present inventive concept, the dummy gate layer D1 may include polysilicon, and the dummy capping layer D2 may include SiNx. The insulating spacer SP may include, for example, silicon nitride, silicon oxide, SiOC, SiOCN, SiCN, SiBN, SiON, SiBCN, SiOF, SiOCH, or a combination thereof. The dummy gate structures DGS may function as an etch mask and may be used to etch the upper stack S2 and the insulating layer 106.

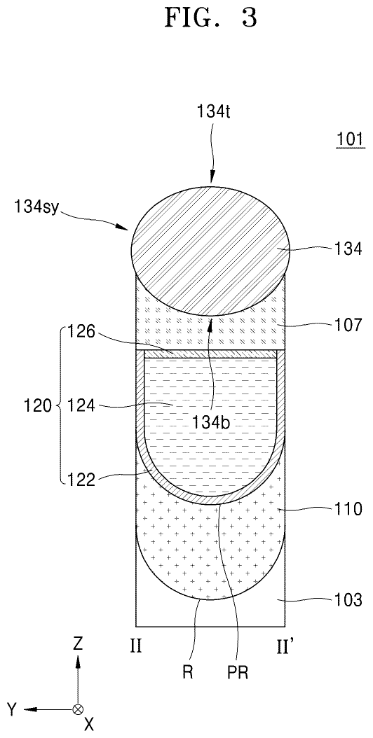

FIG. 3 is a cross-sectional view taken along line II-II′ in FIG. 1, according to embodiments of the present inventive concept. Redundant descriptions given with reference to FIGS. 1 to 2B are omitted, and the differences therefrom are mainly described below.

Referring to FIG. 3, a surface formed by the top surface 134t and the bottom surface 134b of the upper center impurity layer 134 of a semiconductor device 101 and the sidewall 134sy of the upper center impurity layer 134 in the second horizontal direction Y may have a curve that is close to a circle. In other words, the top surface 134t and the bottom surface 134b of the upper center impurity layer 134 and the sidewall 134sy of the upper center impurity layer 134 in the second horizontal direction Y may have substantially the same radius of curvature. In other words, the shape of a cross-section of the upper center impurity layer 134 cut along a plane, which is formed by the second horizontal direction Y and the vertical direction Z, may be a circle or close to a circle. For example, the circular shape of the upper center impurity layer 134 may have a fixed radius.

The top surface 134t and the bottom surface 134b of the upper center impurity layer 134 and the sidewall 134sy of the upper center impurity layer 134 in the second horizontal direction Y may have substantially the same radius of curvature because of a method of forming the upper center impurity layer 134. This is described in detail with reference to FIGS. 20 and 21 below.

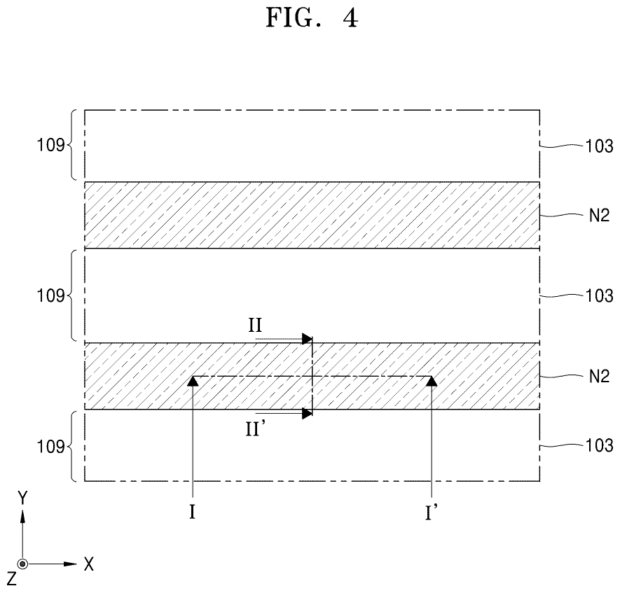

FIGS. 4 to 21 are plan views and cross-sectional views illustrating a method of manufacturing a semiconductor device, according to an embodiment of the present inventive concept. A method of manufacturing the semiconductor devices 100 and 101 is described below with reference to FIGS. 4 to 21.

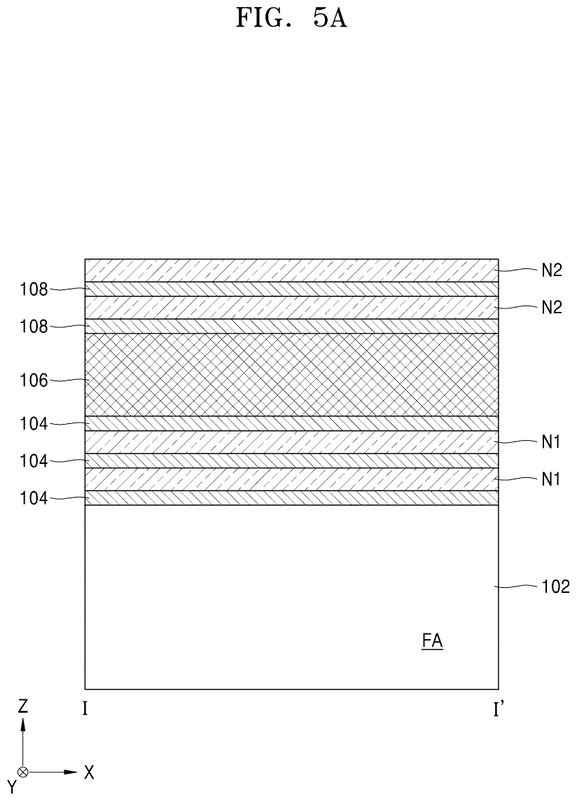

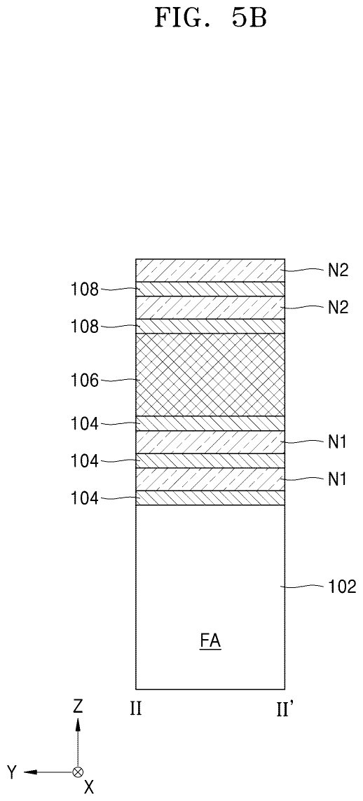

FIG. 4 is a plan view illustrating the method of manufacturing the semiconductor devices 100 and 101. FIGS. 5A and 5B are cross-sectional views respectively taken along line I-I′ and line II-II′ in FIG. 4. Referring to FIGS. 4, 5A, and 5B, lower sacrificial semiconductor layers 104 and lower nanosheet semiconductor layers N1 may be alternately stacked on the substrate 102.

The insulating layer 106 may be formed on the stack structure of the lower sacrificial semiconductor layers 104 and the lower nanosheet semiconductor layers N1. Upper sacrificial semiconductor layers 108 and upper nanosheet semiconductor layers N2 may be alternately stacked on the insulating layer 106.

Thereafter, isolation trenches 109 may be formed by partially etching the upper sacrificial semiconductor layers 108, the upper nanosheet semiconductor layers N2, the insulating layer 106, the lower sacrificial semiconductor layers 104, the lower nanosheet semiconductor layers N1, and the substrate 102 in the first horizontal direction X.

A plurality of fin-type active regions FA may be defined in the substrate 102 by the isolation trenches 109. The fin-type active regions FA may extend in the first horizontal direction X and may be spaced apart from each other in the second horizontal direction Y. Thereafter, isolation films 103 may be formed by filling the isolation trenches 109 with an insulating material.

The lower and upper sacrificial semiconductor layers 104 and 108 may be constituted of a semiconductor material having a different etch selectivity than that of the lower and upper nanosheet semiconductor layers N1 and N2. In embodiments of the present inventive concept, the lower and upper nanosheet semiconductor layers N1 and N2 may be constituted of Si and the lower and upper sacrificial semiconductor layers 104 and 108 may be constituted of SiGe. In embodiments of the present inventive concept, a Ge concentration that is in the lower and upper sacrificial semiconductor layers 104 and 108 may be substantially constant.

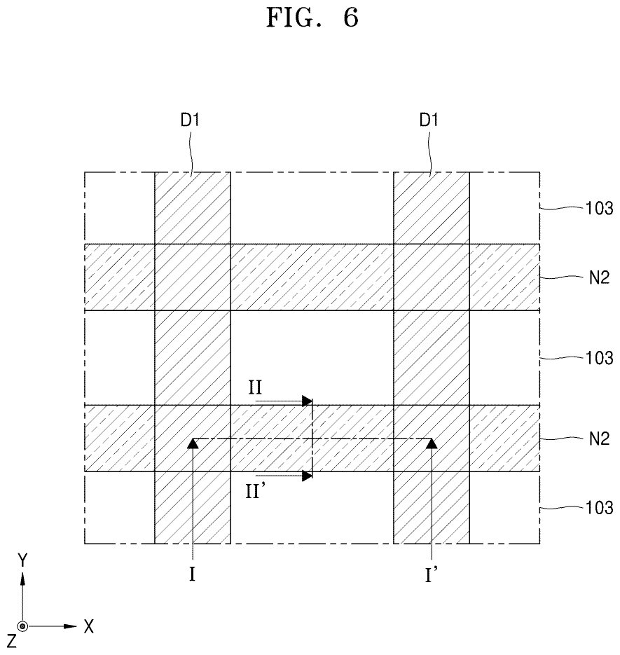

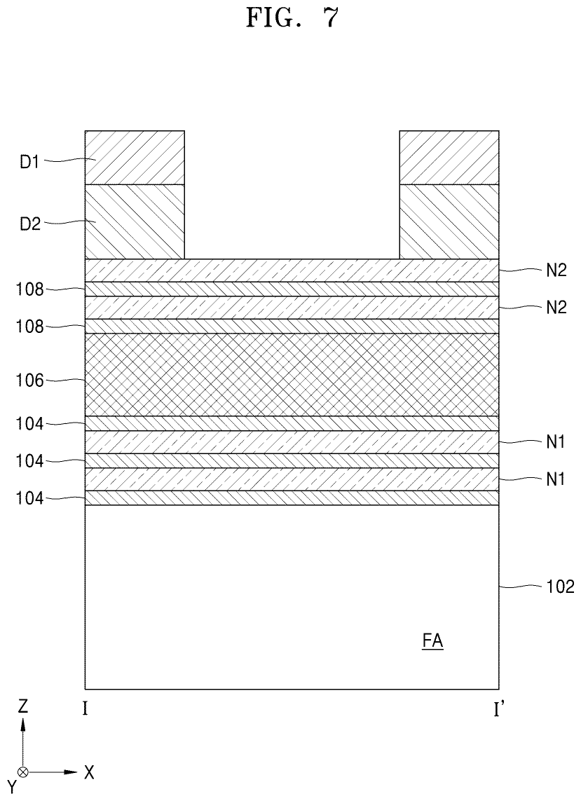

FIG. 6 is a plan view illustrating the method of manufacturing the semiconductor devices 100 and 101. FIG. 7 is a cross-sectional view taken along line I-I′ in FIG. 6. Referring to FIGS. 6 and 7, the dummy gate layer D1 and the dummy capping layer D2 may be sequentially stacked on the stack structure of the lower and upper sacrificial semiconductor layers 104 and 108, the insulating layer 106, and the lower and upper nanosheet semiconductor layers N1 and N2, which are disposed on the fin-type active regions FA. A plurality of stack structures, in which the dummy gate layer D1 and the dummy capping layer D2 are sequentially stacked, may extend in the second horizontal direction Y and may be spaced apart from each other in the first horizontal direction X.

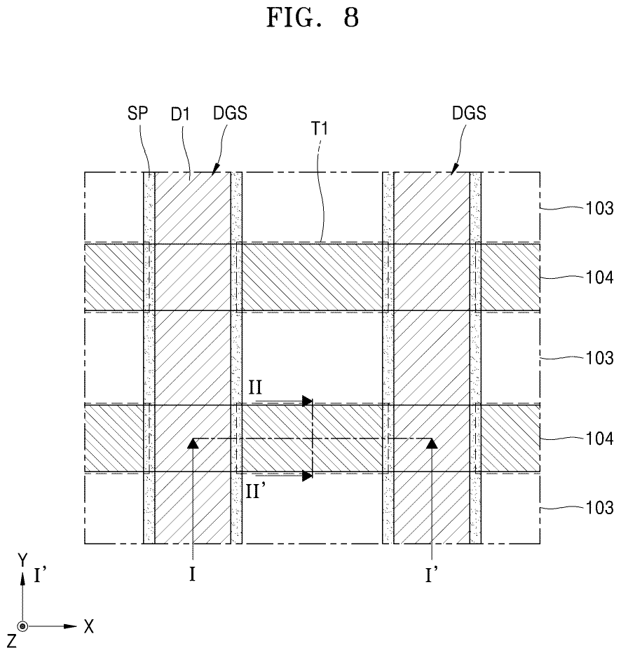

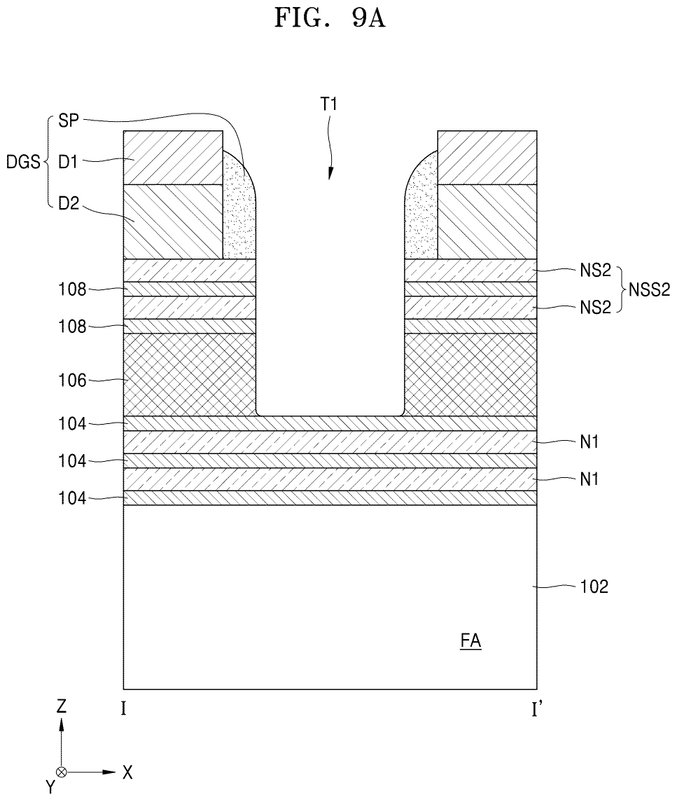

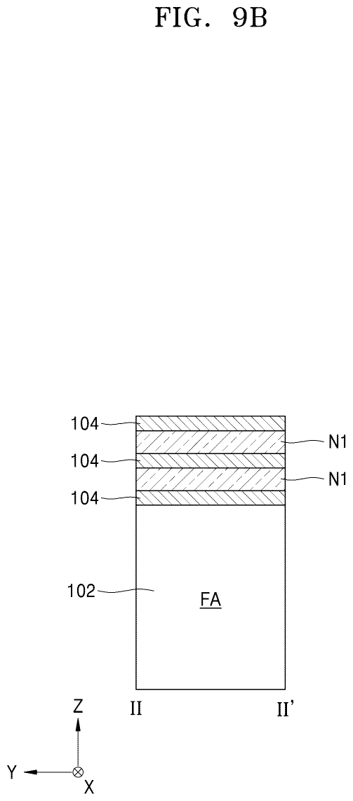

FIG. 8 is a plan view illustrating the method of manufacturing the semiconductor devices 100 and 101. FIGS. 9A and 9B are cross-sectional views respectively taken along line I-I′ and line II-II′ in FIG. 8. Referring to FIGS. 8, 9A, and 9B, an insulating spacer SP may be formed to cover each of opposite sidewalls of each stack structure including the dummy gate layer D1 and the dummy capping layer D2.

The dummy gate layer D1, the dummy capping layer D2, and the insulating spacer SP may form a dummy gate structure DGS. Thereafter, a first trench T1 may be formed by etching the upper sacrificial semiconductor layers 108, the upper nanosheet semiconductor layers N2, and the insulating layer 106 in the vertical direction Z by using the dummy gate structure DGS as an etch mask. The upper nanosheet semiconductor layers N2 may be divided into a plurality of upper nanosheet stacks NSS2 by the first trench T1. Each of the upper nanosheet stacks NSS2 may include a plurality of upper nanosheets NS2. The top surface of a topmost lower sacrificial semiconductor layer 104 among the lower sacrificial semiconductor layers 104 may be exposed by the first trench T1.

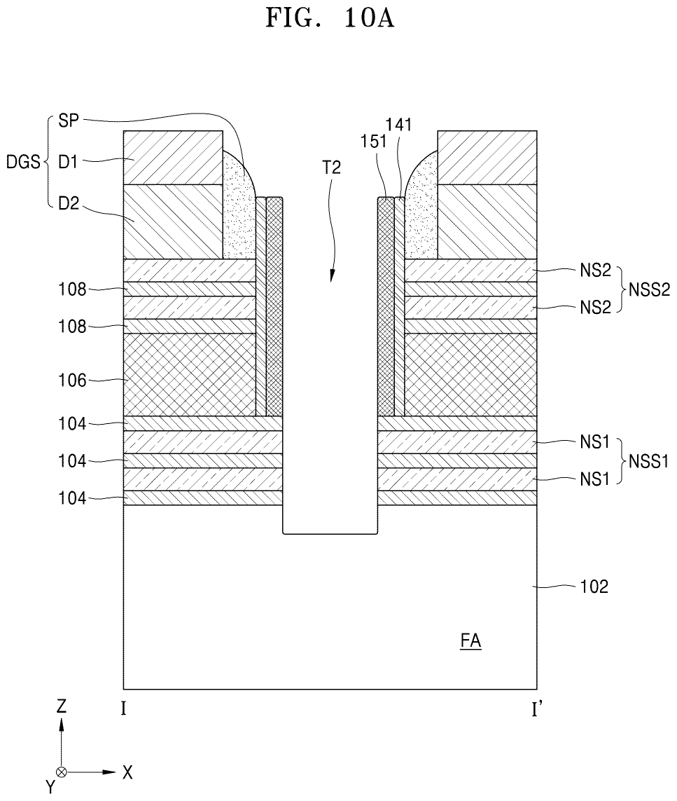

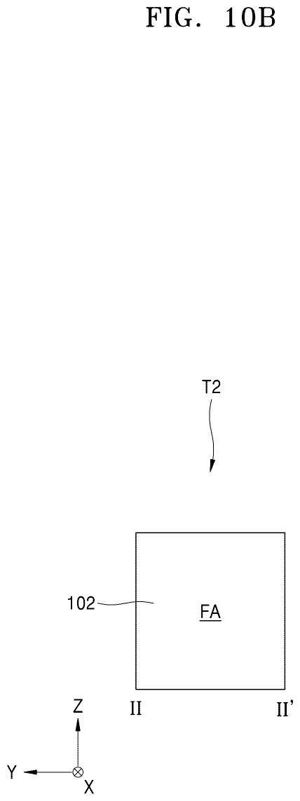

FIGS. 10A and 10B are cross-sectional views respectively taken along line I-I′ and line II-II′ in FIG. 8. Referring to FIGS. 8, 10A, and 10B, a first side liner 141 may be formed on the inner wall of the first trench T1. In other words, the first side liner 141 may be formed to cover the sidewalls of the insulating layer 106, the upper sacrificial semiconductor layers 108, and the upper nanosheets NS2, which are exposed by the first trench T1. The first side liner 141 may extend in the vertical direction Z across a portion of the insulating spacer SP, the upper nanosheets NS2, the upper sacrificial semiconductor layers 108, and the insulating layer 106.

A second side liner 151 may be formed on the inner side of the first side liner 141. The first side liner 141 and the second side liner 151 may include different kinds of materials having high etch selectivities. In an embodiment of the present inventive concept, the first side liner 141 may include SiN, SiO, or SiON, and the second side liner 151 may include AlO, cubic boron nitride (c-BN), amorphous boron nitride (a-BN), or carbon-doped amorphous boron nitride (a-BN:C).

Thereafter, a second trench T2 may be formed by etching the lower sacrificial semiconductor layers 104, the lower nanosheet semiconductor layers N1, and an upper portion of a fin-type active region FA in the vertical direction Z by using the dummy gate structure DGS, the first side liner 141, and the second side liner 151 as an etch mask.

The lower nanosheet semiconductor layers N1 may be divided into a plurality of lower nanosheet stacks NSS1 by the second trench T2. Each of the lower nanosheet stacks NSS1 may include a plurality of lower nanosheets NS1.

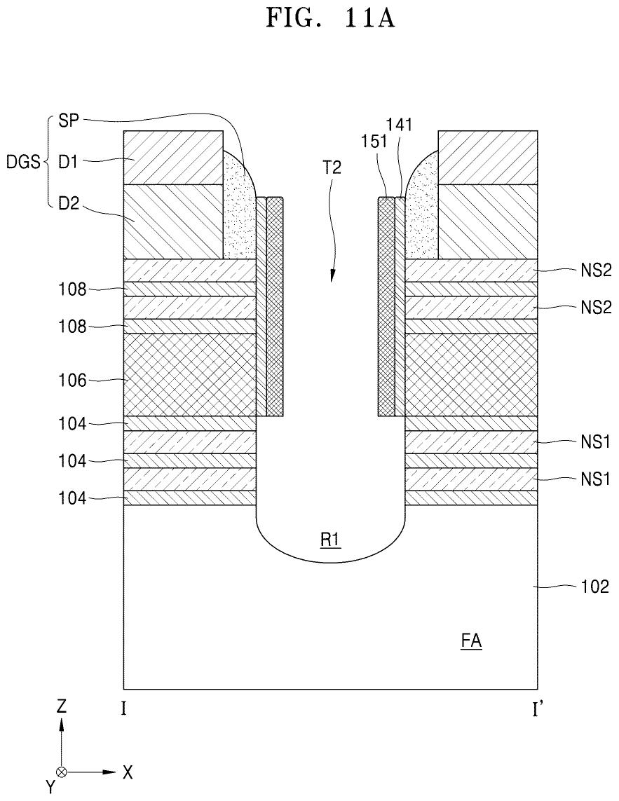

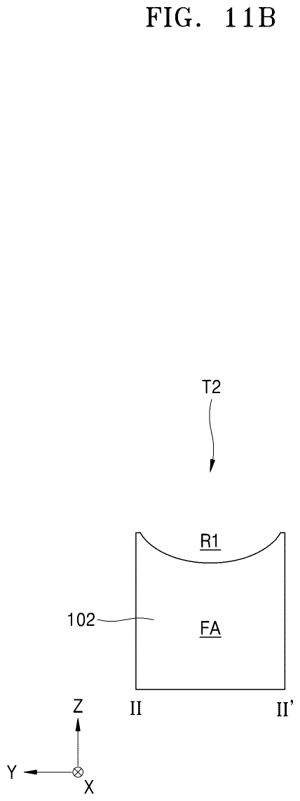

FIGS. 11A and 11B are cross-sectional views respectively taken along line I-I′ and line II-II′ in FIG. 8. Referring to FIGS. 8, 11A, and 11B, a lower portion of the second trench T2 may be expanded.

The lower portion of the second trench T2 may be formed by further etching portions of the lower sacrificial semiconductor layers 104, the lower nanosheets NS1, and the fin-type active region FA, which are disposed below the first side liner 141 and the second side liner 151.

Accordingly, a first recess R1 may be formed in an upper portion of the fin-type active region FA. Here, the first recess R1 may refer to only a portion in the fin-type active region FA, and the second trench T2 may include the first recess R1 and may be defined by the top surface of the upper nanosheet stacks NSS2, the lower nanosheet stacks NSS1, and the bottom surface of the first recess R1.

In embodiments of the present inventive concept, the process of expanding a lower portion of the second trench T2 may be omitted. In this case, the second trench T2 in FIGS. 10A and 10B may include the first recess R1 formed in the upper portion of the fin-type active region FA.

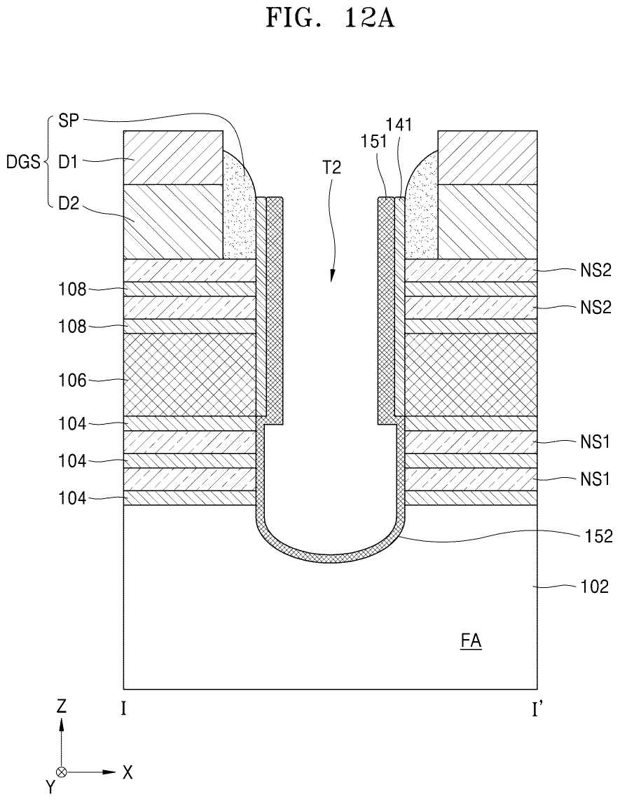

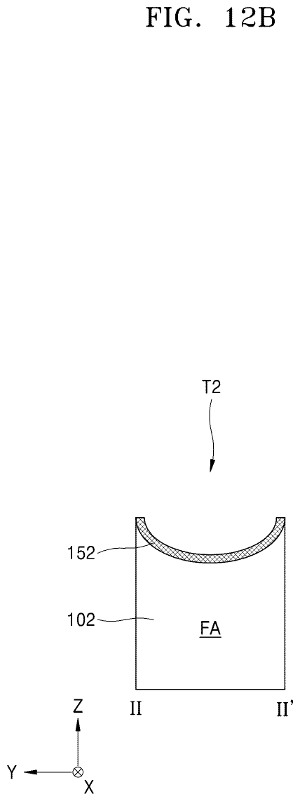

FIGS. 12A and 12B are cross-sectional views respectively taken along line I-I′ and line II-II′ in FIG. 8. Referring to FIGS. 8, 12A, and 12B, a second lower liner 152 may be formed on the lower sacrificial semiconductor layers 104, the lower nanosheets NS1, and the fin-type active region FA, which are exposed by the lower portion of the second trench T2. The second lower liner 152 may include the same material as the second side liner 151.

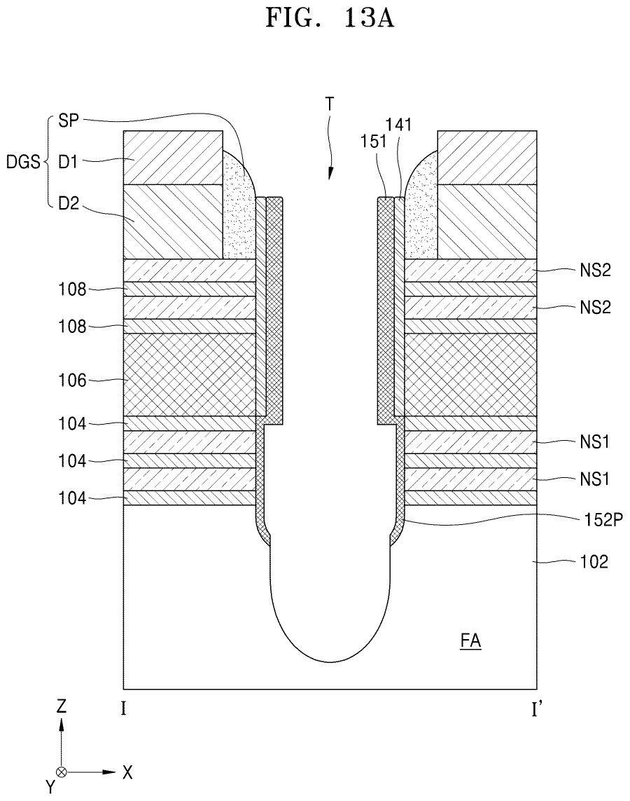

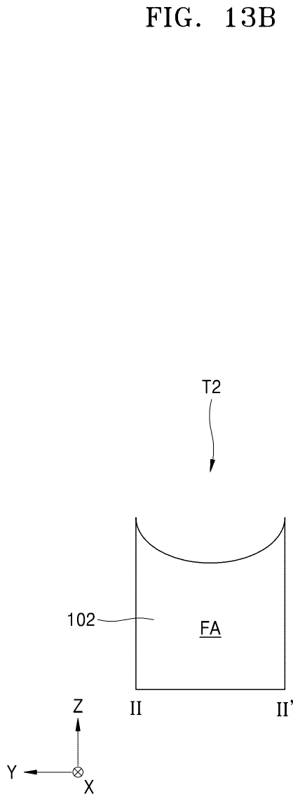

FIGS. 13A and 13B are cross-sectional views respectively taken along line I-I′ and line II-II′ in FIG. 8. Referring to FIGS. 8, 13A, and 13B, a trench T may be formed by etching a portion of the second lower liner 152 and the fin-type active region FA that is below the second lower liner 152. In this process, the portion of the second lower liner 152 may be removed, and a second local liner 152p may remain. For example, the portion of the second lower liner 152 that may be removed may be a portion that is in contact with the fin-type active region FA.

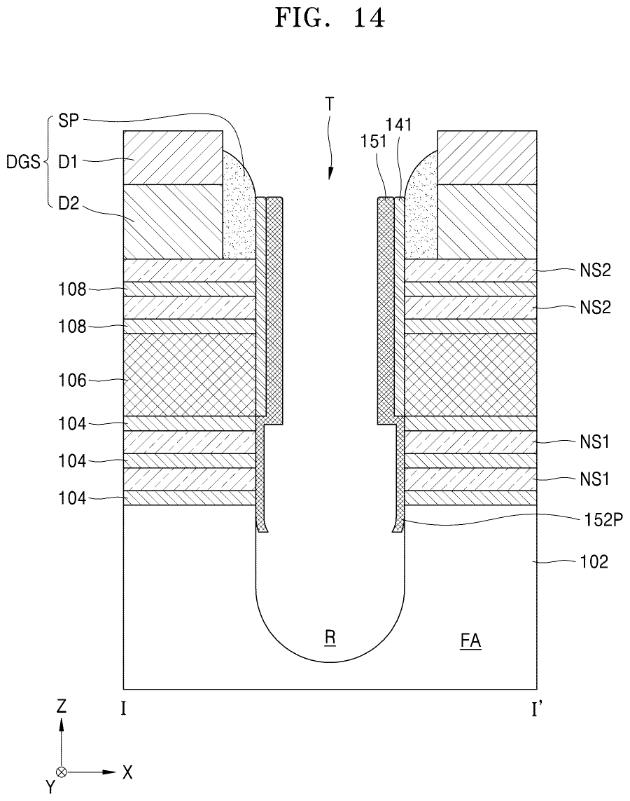

FIG. 14 is a cross-sectional view taken along line I-I′ in FIG. 8. Referring to FIGS. 8 and 14, a lower portion of the trench T may be expanded.

The lower portion of the trench T may be formed by further etching a portion of the fin-type active region FA and a portion of the second local liner 152p. Accordingly, a recess R may be formed in an upper portion of the fin-type active region FA.

Here, the recess R may refer to a portion in the fin-type active region FA, and the trench T may include the recess R and may be defined by the top surface of the upper nanosheet stacks NSS2, the lower nanosheet stack NSS1, and the bottom surface of the recess R.

In embodiments of the present inventive concept, the process of expanding a lower portion of the trench T may be omitted. In this case, the trench T in FIGS. 13A and 13B may include the recess R formed in the upper portion of the fin-type active region FA.

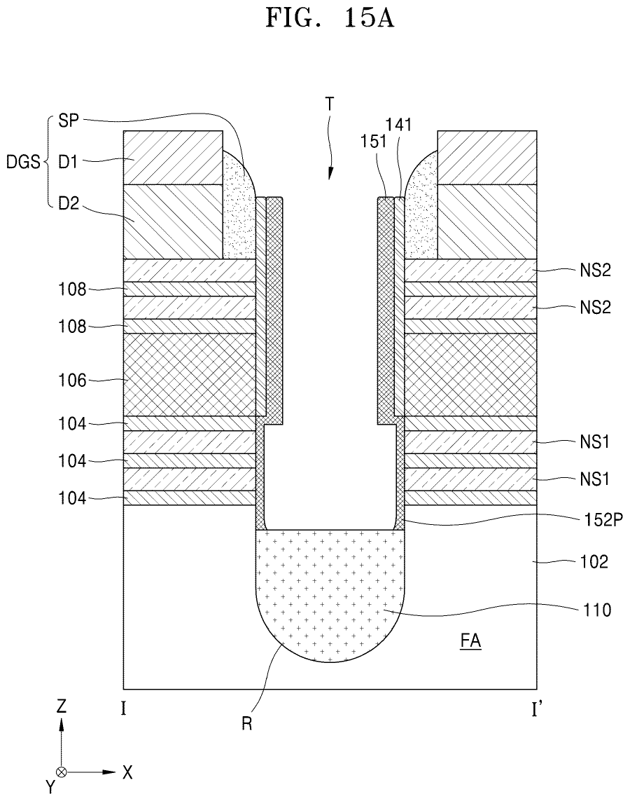

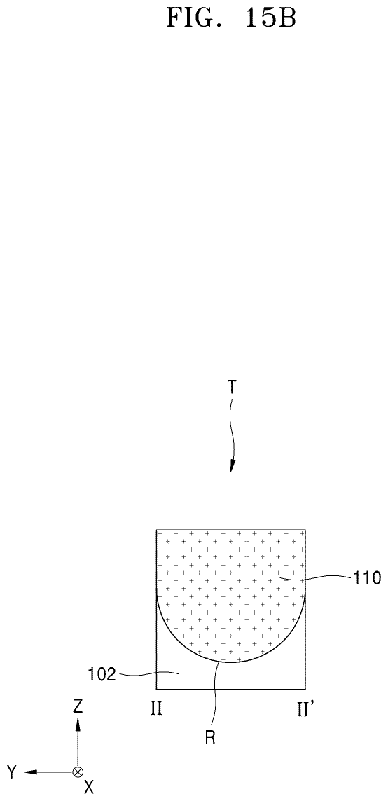

FIGS. 15A and 15B are cross-sectional views respectively taken along line I-I′ and line II-II′ in FIG. 8. Referring to FIGS. 8, 15A, and 15B, the placeholder 110 may be formed in a lower portion of the trench T. The placeholder 110 may be formed by epitaxial growth in the recess R of the fin-type active region FA. In an embodiment of the present inventive concept, the placeholder 110 may include an epitaxially grown SiGe layer.

The placeholder 110 might not rise above the second local liner 152p. In other words, the height of the placeholder 110 may be less than or equal to the vertical distance between the lowest point of the recess R and the bottom surface of the second local liner 152p

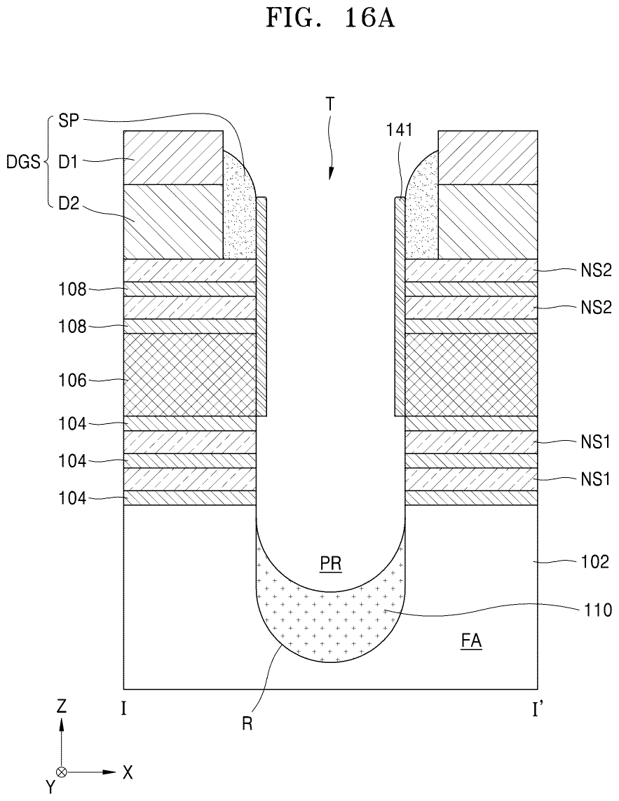

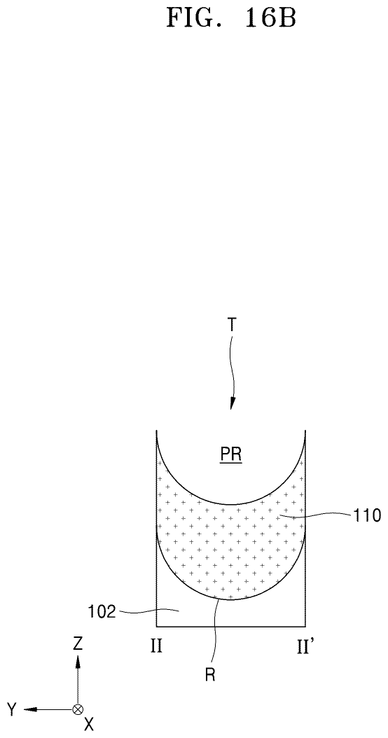

FIGS. 16A and 16B are cross-sectional views respectively taken along line I-I′ and line II-II′ in FIG. 8. Referring to FIGS. 8, 16A, and 16B, the second side liner 151 and the second local liner 152p may be removed, and an upper portion of the placeholder 110 may be etched.

In an embodiment of the present inventive concept, an etchant including HF may be used to selectively remove the second side liner 151 and the second local liner 152p, but embodiments of the present inventive concept are not limited thereto.

Because the second side liner 151 and the second local liner 152p have a high etch selectivity with respect to the first side liner 141, the first side liner 141 might not be removed but may remain on the sidewalls of the insulating layer 106, the upper sacrificial semiconductor layers 108, and the upper nanosheet semiconductor layers N2 even when the second side liner 151 and the second local liner 152p are removed. The placeholder recess PR may be formed in the upper portion of the placeholder 110.

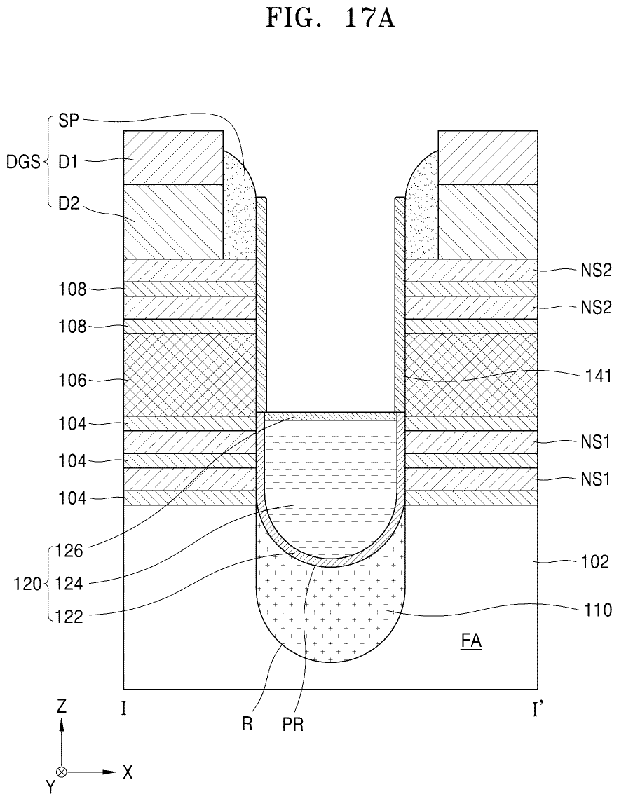

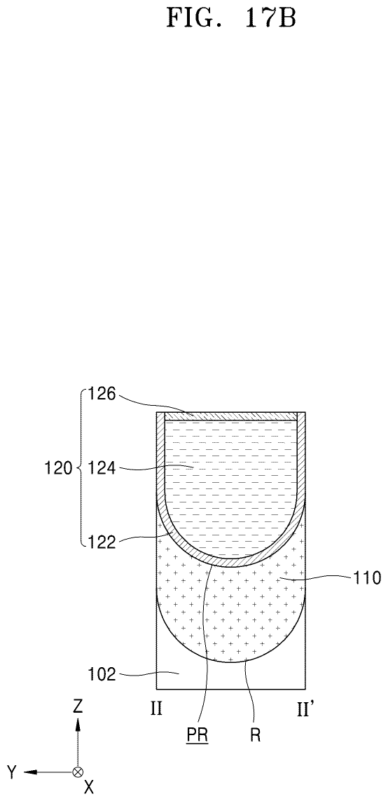

FIGS. 17A and 17B are cross-sectional views respectively taken along line I-I′ and line II-II′ in FIG. 8. Referring to FIGS. 8, 17A, and 17B, the lower source/drain region 120 may be formed on the placeholder recess PR.

The lower source/drain region 120 may be formed on the side surfaces of the lower sacrificial semiconductor layers 104 and the lower nanosheets NS1 by growing an epitaxial layer on the placeholder recess PR to fill the trench T. The first side liner 141 may remain on the sidewalls of the insulating layer 106, the upper sacrificial semiconductor layers 108, and the upper nanosheets NS2, and the lower source/drain region 120 might not be grown in a portion where the first side liner 141 is located. For example, the lower source/drain region 120 might not be grown beyond a lower surface of the first side liner 141.

To form the lower source/drain region 120, the outer impurity layer 122, the lower center impurity layer 124, and the capping layer 126 may be sequentially formed in an inner space that is defined by the side surfaces of the lower sacrificial semiconductor layers 104 and the lower nanosheets NS1 and may be disposed in the placeholder recess PR. For example, to form the lower source/drain region 120, a semiconductor material may be epitaxially grown from the top surface of the placeholder 110 and the side surfaces of the lower sacrificial semiconductor layers 104 and the lower nanosheets NS1.

In embodiments of the present inventive concept, to form the lower source/drain region 120, low-pressure chemical vapor deposition (LPCVD) or selective epitaxial growth (SEG) may be performed using raw materials including an elemental semiconductor precursor. The elemental semiconductor precursor may include an element, such as Si or Ge.

When the lower source/drain region 120 is formed, SiH₄, SiHCl₃, Si₂H₆, Si₃H₈, SiH₂Cl₂, or the like may be used as an Si source to form the outer impurity layer 122 and/or the lower center impurity layer 124. However, the Si source is not limited to those materials mentioned above. In addition, various kinds of gaseous or liquid dopants may be used as materials with which the outer impurity layer 122 and/or the lower center impurity layer 124 is doped. An etchant gas, such as HCl or Cl₂, may be used for selective epitaxial growth.

As described above, the outer impurity layer 122 may include, for example, SiGe doped with P, As, Pd, or the like. Compared to the outer impurity layer 122, the lower center impurity layer 124 may include SiGe having a high Ge concentration. The capping layer 126 may include, for example, undoped Si or SiGe with a low concentration of Gc.

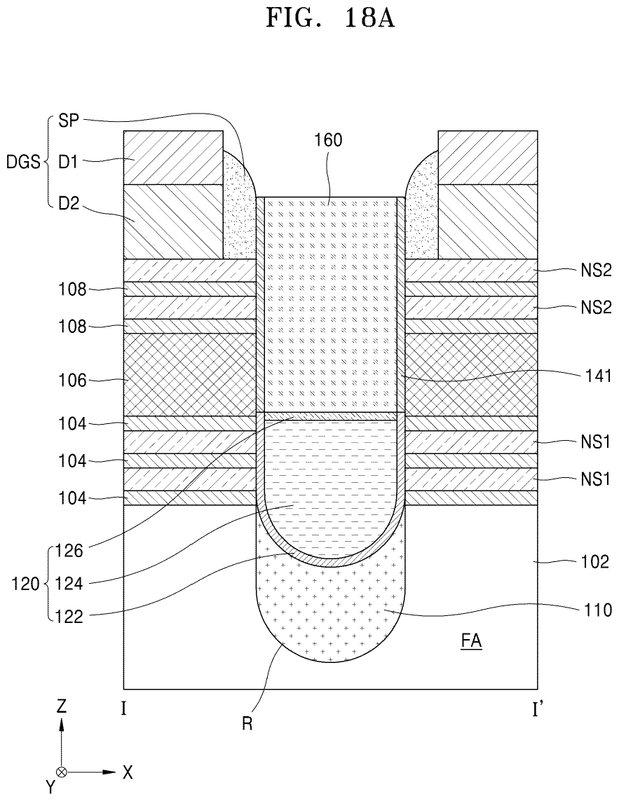

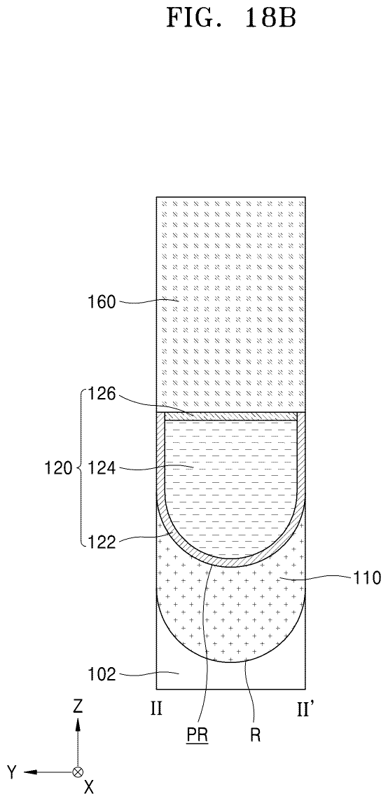

FIGS. 18A and 18B are cross-sectional views respectively taken along line I-I′ and line II-II′ in FIG. 8. Referring to FIGS. 8, 18A, and 18B, a sacrificial film 160 may be formed in a space that is surrounded by the first side liner 141 and the capping layer 126. The vertical level of the top surface of the sacrificial film 160 may be substantially the same as the vertical level of the top surface of the first side liner 141, but embodiments of the present inventive concept are not limited thereto.

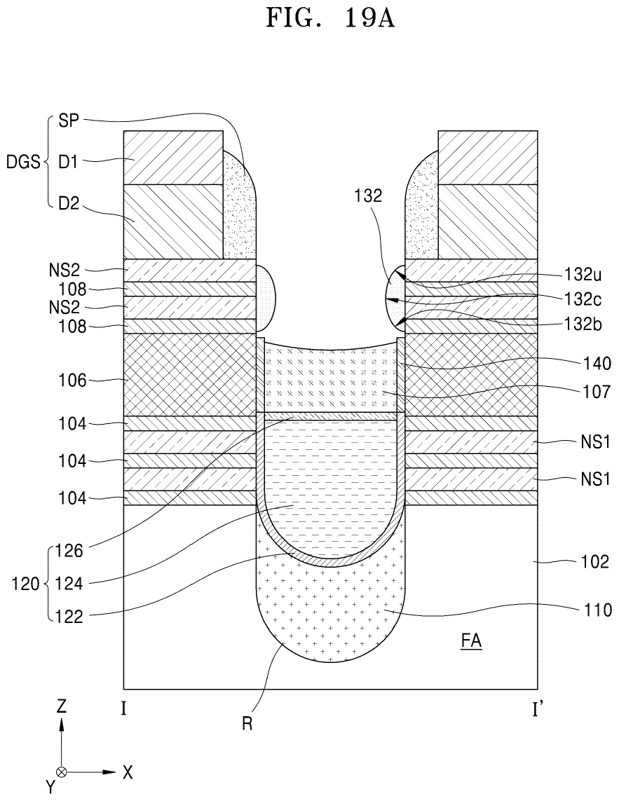

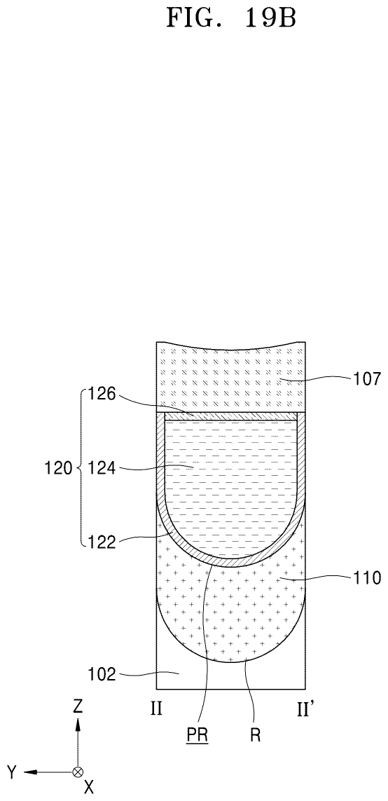

FIGS. 19A and 19B are cross-sectional views respectively taken along line I-I′ and line II-II′ in FIG. 8. Referring to FIGS. 8, 19A, and 19B, a portion of the sacrificial film 160 and a portion of the first side liner 141 may be recessed. As a result, the insulating film 107 may be formed from the sacrificial film 160, and the liner 140 may be formed from the first side liner 141.

The side impurity layer 132 may be formed on the side surfaces of the upper sacrificial semiconductor layers 108 and the upper nanosheets NS2. For example, to form the side impurity layer 132, a semiconductor material may be epitaxially grown from the side surfaces of the upper sacrificial semiconductor layers 108 and the upper nanosheets NS2.

In embodiments of the present inventive concept, to form the side impurity layer 132, LPCVD or SEG may be performed using raw materials including an elemental semiconductor precursor. The elemental semiconductor precursor may include an element, such as Si or Ge.

When the side impurity layer 132 is formed, SiH₄, SiHCl₃, Si₂H₆, Si₃H₈, SiH₂Cl₂, or the like may be used as an Si source. However, the Si source is not limited to those materials mentioned above. In addition, various kinds of gaseous or liquid dopants may be used as materials with which the side impurity layer 132 is doped. An etchant gas, such as HCl or Cl₂, may be used for selective epitaxial growth.

The side impurity layer 132 may include a central region 132c, an upper region 132u, and a lower region 132b. The central region 132c of the side impurity layer 132 may correspond to a central portion of the side impurity layer 132 and include a portion having the greatest thickness in the side impurity layer 132 in the first horizontal direction X. For example, the thickness of the central region 132c may be greater than each of the thickness of the lower region 132b and the thickness of the upper region 132u. For example, the side impurity layer 132 may have a rounded side surface.

The upper region 132u of the side impurity layer 132 may correspond to a portion of the side impurity layer 132, which extends upwards (in the vertical direction Z) from the central region 132c of the side impurity layer 132. The lower region 132b of the side impurity layer 132 may correspond to a portion of the side impurity layer 132, which extends downwards (in the vertical direction Z) from the central region 132c of the side impurity layer 132.

The side impurity layer 132 may include, for example, Si, SiGe, or SiC, which is doped with B. Desirably, the side impurity layer 132 may include, for example, SiGe doped with B.

FIGS. 20 and 21 are cross-sectional views taken along line I-I′ in FIG. 8. Referring to FIGS. 8 and 20, an epitaxial layer 134p may be formed on the surface of the side impurity layer 132. For example, to form the epitaxial layer 134p, a semiconductor material may be epitaxially grown from the surface of the side impurity layer 132.

In embodiments of the present inventive concept, to form the epitaxial layer 134p, LPCVD or SEG may be performed by using raw materials including an elemental semiconductor precursor. The elemental semiconductor precursor may include an element, such as Si or Ge.

When the epitaxial layer 134p is formed, SiH₄, SiHCl₃, Si₂H₆, Si₃H₈, SiH₂Cl₂, or the like may be used as an Si source. However, the Si source is not limited to those materials mentioned above. For example, GeCl, GeH₄, or a combination thereof may be used as a Ge source.

Various kinds of gaseous or liquid dopants may be used as materials with which the epitaxial layer 134p is doped.

The epitaxial layer 134p may include, for example, Si, SiGe, or SiC. The epitaxial layer 134p may be grown in the direction of a certain crystal plane of Si, SiGe, or SiC. For example, when the epitaxial layer 134p includes SiGe, the epitaxial layer 134p may be grown on the crystal plane. Accordingly, the surface of the epitaxial layer 134p may be straight and have a pointed portion.

When the epitaxial layer 134p is formed, the epitaxial layer 134p may be doped with B in situ. In the process of forming the epitaxial layer 134p, the epitaxial layer 134p may be doped with B by providing a precursor including B.

The epitaxial layer 134p may cover the upper region 132u, the central region 132c, and the lower region 132b of the side impurity layer 132.

Referring to FIG. 21, a portion of the epitaxial layer 134p may be removed by performing an etching process on the epitaxial layer 134p in FIG. 20. During the etching process, an etchant gas, such as HCl or Cl₂, may be used. At this time, the temperature of the etching process may increase. As the etching process temperature increases, a reflow phenomenon may occur in the epitaxial layer 134p. As atoms in the epitaxial layer 134p are rearranged due to the reflow phenomenon, the surface of the epitaxial layer 134p may become round due to surface tension. Accordingly, the surface of the epitaxial layer 134p may have a curved shape.

According to the descriptions made with reference to FIGS. 20 and 21, the epitaxial layer 134p may be formed by repeating a cycle of deposition and etching. In other words, the epitaxial layer 134p may be formed using a cyclic deposition and an etching (CDE) process.

Referring back to FIGS. 1, 2A, and 2B, the volume of the epitaxial layer 134p may increase by performing the CDE process multiple times. Accordingly, the upper center impurity layer 134 may be formed from the epitaxial layer 134p. As described above with reference to FIGS. 20 and 21, each of the top surface 134t and the bottom surface 134b of the upper center impurity layer 134 and the sidewall 134sy of the upper center impurity layer 134 in the second horizontal direction Y may have a curved shape due to the surface tension of the upper center impurity layer 134.

When only an LPCVD process or SEG process is used to form the upper center impurity layer 134 and the distance between two adjacent upper nanosheets NS2 in the first horizontal direction X is relatively long, the upper center impurity layer 134 might not be completely formed. This is because the process may end before the epitaxial layers 134p that are growing in opposite directions meet with each other. In this case, the electrical characteristics and reliability of the semiconductor device 100 may deteriorate.

However, it is difficult to carry out the LPCVD or SEG process for a long time. When the LPCVD or SEG process is carried out for a long time, the upper center impurity layer 134 may over grow in a portion, in which the distance between two adjacent upper nanosheets NS2 in the first horizontal direction X may be relatively short, resulting in a short circuit with adjacent conductive components.

According to embodiments of the inventive concept, a method of manufacturing the semiconductor device 100 may use a CDE process to form the upper center impurity layer 134. In this case, regardless of the distance between two adjacent upper nanosheets NS2 in the first horizontal direction X, the upper center impurity layer 134 may be formed from the epitaxial layer 134p. Accordingly, the electrical characteristics and reliability of the semiconductor device 100 may increase.

Due to the CDE process, each of the top surface 134t and the bottom surface 134b of the upper center impurity layer 134 and the sidewall 134sy of the upper center impurity layer 134 in the second horizontal direction Y may have a curved shape.

The lower sacrificial semiconductor layers 104 and the upper sacrificial semiconductor layers 108, which remain on the fin-type active region FA, may be removed, and the lower gate dielectric film GD1, the lower gate line GL1, the upper gate dielectric film GD2, and the upper gate line GL2 may be formed.

To selectively remove the lower sacrificial semiconductor layers 104 and the upper sacrificial semiconductor layers 108, a liquid or gaseous etchant may be used. In embodiments of the present inventive concept, a CH₃COOH-based etchant, e.g., an etchant including a mixture of CH₃COOH, HNO₃, and HF or an etchant including a mixture of CH₃COOH, H₂O₂, and HF, may be used, but embodiments of the present inventive concept are not limited thereto.

The lower gate dielectric film GD1 may be formed to cover a lower nanosheet NS1, the exposed surface the fin-type active region FA, and the bottom surface of the insulating layer 106. The upper gate dielectric film GD2 may be formed to cover an upper nanosheet NS2 and the top surface of the insulating layer 106. For example, the lower gate dielectric film GD1 and the upper gate dielectric film GD2 may be formed by using an atomic layer deposition (ALD) process.

The lower gate line GL1 may be formed on the lower gate dielectric film GD1, and the upper gate line GL2 may be formed on the upper gate dielectric film GD2. In embodiments of the present inventive concept, the lower gate line GL1 and the upper gate line GL2 each may include metal, metal nitride, metal carbide, or a combination thereof.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor device comprising:
a lower stack including a plurality of lower gate lines and a plurality of lower nanosheets that are alternately stacked layer-by-layer on a substrate;
an upper stack including a plurality of upper gate lines and a plurality of upper nanosheets that are alternately stacked layer-by-layer on the lower stack;
a lower source/drain region disposed on a side surface of the lower stack; and
an upper source/drain region disposed on the lower source/drain region and adjacent to a side surface of the upper stack,
wherein the upper source/drain region includes a side impurity layer and an upper center impurity layer, wherein the side impurity layer extends in a vertical direction along the side surface of the upper stack, and the upper center impurity layer is disposed on an inner side of the side impurity layer, and
a first surface of the upper center impurity layer has a curved shape.

2. The semiconductor device of claim 1, wherein a second surface of the upper center impurity layer has a curved shape.

3. The semiconductor device of claim 1, wherein
the lower source/drain region includes a semiconductor material that is doped with an n-type dopant, and
the upper source/drain region includes a semiconductor material that is doped with a p-type dopant.

4. The semiconductor device of claim 3, wherein
the upper source/drain region includes a semiconductor material that is doped with boron (B), and
a B concentration that is in the upper center impurity layer is greater than a B that is concentration in the side impurity layer.

5. The semiconductor device of claim 4, wherein
the B concentration in the upper center impurity layer is about 10¹⁶ atoms/cm³ to about 10¹⁹ atoms/cm³.

6. The semiconductor device of claim 1, wherein
each of the upper center impurity layer and the side impurity layer includes SiGe, and
a Ge concentration that is in the upper center impurity layer is greater than a Ge concentration that is in the side impurity layer.

7. The semiconductor device of claim 6, wherein
the Ge concentration that is in the upper center impurity layer is greater than about 30 wt % and less than or equal to about 60 wt %.

8. The semiconductor device of claim 1, wherein a second surface of the upper center impurity layer has a curved shape.

9. The semiconductor device of claim 8, wherein
a radius of curvature of the first surface of the upper center impurity layer is substantially identical to a radius of curvature of the second surface of the upper center impurity layer.

10. The semiconductor device of claim 1, wherein
the side impurity layer includes a central region, an upper region, and a lower region, wherein the upper region extends upwards from the central region, and the lower region extends downwards from the central region, and
the upper center impurity layer covers a topmost surface of the upper region of the side impurity layer.

11. The semiconductor device of claim 10, wherein the upper center impurity layer covers a bottommost surface of the lower region.

12. A semiconductor device comprising:
a lower stack including a plurality of lower gate lines and a plurality of lower nanosheets that are alternately stacked layer-by-layer on a substrate, wherein the plurality of lower gate lines extend in a first horizontal direction;
an upper stack including a plurality of upper gate lines and a plurality of upper nanosheets that are alternately stacked layer-by-layer on the lower stack, wherein the plurality of upper gate lines extending in the first horizontal direction;
a lower source/drain region adjacent to a side surface of the lower stack; and
an upper source/drain region disposed on the lower source/drain region and adjacent to a side surface of the upper stack,
wherein the upper source/drain region includes a side impurity layer and an upper center impurity layer, wherein the side impurity layer extends in a vertical direction along the side surface of the upper stack, and the upper center impurity layer is disposed on first side of the side impurity layer, and
a sidewall of the upper center impurity layer in the first horizontal direction has a curved shape.

13. The semiconductor device of claim 12, wherein a top surface of the upper center impurity layer has a curved shape.

14. The semiconductor device of claim 13, wherein
a radius of curvature of the top surface of the upper center impurity layer is substantially identical to a radius of curvature of the sidewall of the upper center impurity layer in the first horizontal direction.

15. The semiconductor device of claim 12, wherein
a shape of the upper center impurity layer is a circle.

16. The semiconductor device of claim 12, wherein
the lower source/drain region includes a semiconductor material that is doped with an n-type dopant, and
the upper source/drain region includes a semiconductor material that is doped with a p-type dopant.

17. The semiconductor device of claim 16, wherein
the upper source/drain region includes a semiconductor material that is doped with boron (B), and
a B concentration that is in the upper center impurity layer is greater than a B concentration that is in the side impurity layer.

18. The semiconductor device of claim 12, wherein
each of the upper center impurity layer and the side impurity layer includes SiGe, and
a Ge concentration that is in the upper center impurity layer is greater than a Ge concentration that is in the side impurity layer.

19. A semiconductor device comprising:
a substrate including a fin-type active region that extends in a first horizontal direction;
a lower stack including a plurality of lower gate lines and a plurality of lower nanosheets that are alternately stacked layer-by-layer on the fin-type active region of the substrate, wherein the plurality of lower gate lines extend in a second horizontal direction that crosses the first horizontal direction;
an insulating layer disposed on the lower stack;
an upper stack including a plurality of upper gate lines and a plurality of upper nanosheets that are alternately stacked layer-by-layer on the insulating layer, wherein the plurality of upper gate lines extend in the second horizontal direction;
a placeholder arranged in the substrate and below the lower stack;
a lower source/drain region disposed on the placeholder and adjacent to a side surface of the lower stack; and
an upper source/drain region adjacent to a side surface of the upper stack,
wherein the upper source/drain region includes a side impurity layer and an upper center impurity layer, wherein the side impurity layer extends in a vertical direction along the side surface of the upper stack, and the upper center impurity layer is disposed on an inner side of the side impurity layer, and
a top surface of the upper center impurity layer has a curved shape.

20. The semiconductor device of claim 19, wherein
a sidewall of the upper center impurity layer in the second horizontal direction has a curved shape.
